(19) United States
(12) Patent Application Publication
(10) Pub. No.: US 2021/0056247 A1
(43) Pub. Date: Feb. 25, 2021

(54) POSE DETECTION OF OBJECTS FROM IMAGE DATA

(71) Applicant: Ascent Robotics Inc., Tokyo (JP)

(72) Inventors: Hervé AUDREN, Tokyo (JP); Fernando CAMARO NOGUES, Valencia (ES); Lanke FU, Tokyp (JP); Nathawan CHAROENKULVANICH, Tokyo (JP); Jose Ivan LOPEZ ROMO, Tokyo (JP); Mutsuki SAKAKIBARA, Tokyo (JP); Marko SIMIC, Tokyo (JP)

(21) Appl. No.: 16/999,087

(22) Filed: Aug. 21, 2020

(30) Foreign Application Priority Data
Aug. 21, 2019 (JP) 2019-150869

(51) Int. Cl. G06F 30/27; G06N 3/08; G06T 7/70; G06T 7/00; B25J 9/16; B25J 9/12

(52) U.S. Cl. CPC G06F 30/27; G06N 3/084; B25J 9/12; G06T 7/0002; B25J 9/1697; G06T 7/70

(57) ABSTRACT

Object pose may be detected by obtaining a computer model of a physical object, simulating the computer model in a realistic environment simulator, capturing training data including a plurality of pose representations, each pose representation including an image of the computer model in one of a plurality of poses paired with a label including a pose specification of the computer model as shown in the image, the image of the computer model and the pose specification defined by the simulator, and applying a learning process to the pose representations to produce a pose determining function for relating an image of the object to a pose specification.

### CROSS-REFERENCE TO RELATED APPLICATIONS

This application claims priority to Japanese Patent Application No. 2019-150869 filed on Aug. 21, 2019, the contents of which is hereby incorporated by reference in its entirety.

### BACKGROUND

### Technical Field

The present invention relates to pose detection. More specifically, the present invention relates to pose determining functions trained with simulations of computer model poses.

### Background

Product manufacturing includes an increasing amount of robotics. For example, an assembly line may include robot arms that detect, pick up, and put together parts as the final product is assembled. To reduce the programming burden, human interaction can be increased. For example, by arranging parts by hand in proper position and orientation, a robot arm need only minimal detection capabilities. As robot arms increase their ability to detect and manipulate objects, human interaction may be reduced, which may also reduce manufacturing costs.

To effectively manipulate objects, robotic systems need to be able to recognize how such objects are placed in 6D space, a definition of position along 3 axes and orientation about 3 axes. In order to train and assess the performance of such robotic systems, large amounts of training data, containing much environmental variety, must be obtained. Designers of such robotic systems face challenges trying to maximize accuracy while keeping both runtime and data modality requirements low.

### SUMMARY

According to an aspect of the present invention, provided is a computer program that is executable by a computer to cause the computer to perform operations including obtaining a computer model of a physical object, simulating the computer model in a realistic environment simulator, capturing training data including a plurality of pose representations, each pose representation including an image of the computer model in one of a plurality of poses paired with a label including a pose specification of the computer model as shown in the image, the image of the computer model and the pose specification defined by the simulator, and applying a learning process to the pose representations to produce a pose determining function for relating an image of the object to a pose specification.

This aspect may also include the method performed by the computer executing the instructions of the computer program, and an apparatus that performs the method.

The summary clause does not necessarily describe all necessary features of the embodiments of the present invention. The present invention may also be a sub-combination of the features described above.

### BRIEF DESCRIPTION OF THE DRAWINGS

FIG. 1 shows a diagram of interaction among hardware and software elements from a CAD model to a refined pose detection, according to an embodiment of the present invention.

FIG. 2 shows an exemplary hardware configuration for pose detection, according to an embodiment of the present invention.

FIG. 3 shows an operational flow for pose detection, according to an embodiment of the present invention.

FIG. 4 shows an operational flow for simulation of a computer model to capture training data, according to an embodiment of the present invention.

FIG. 5 shows an operational flow for producing a pose determining function, according to an embodiment of the present invention.

FIG. 6 shows an operational flow for determining a pose specification, according to an embodiment of the present invention.

### DETAILED DESCRIPTION OF EXEMPLARY EMBODIMENTS

Hereinafter, example embodiments of the present invention will be described. The example embodiments shall not limit the invention according to the claims, and the combinations of the features described in the embodiments are not necessarily essential to the invention.

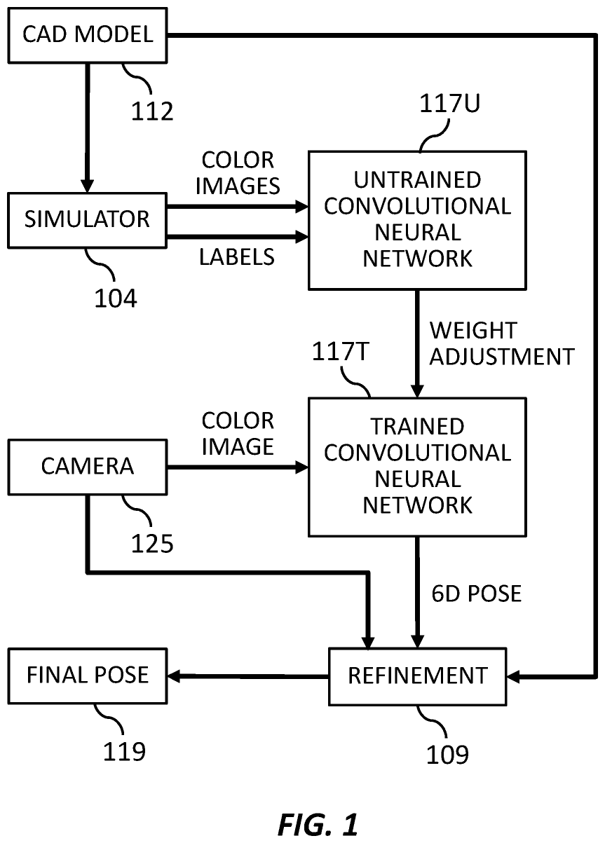

FIG. 1 shows a diagram of interaction among hardware and software elements from a CAD model to a refined pose detection, according to an embodiment of the present invention. This diagram shows a multi-stage approach consisting of simulation, deep learning, and classical computer vision. In this embodiment, a Computer-Aided Design (CAD) model 112 is obtained. CAD model 112 may be prepared from a 3D scan of a physical object or manually designed. In some cases, such as assembly lines, CAD models may already be prepared, and can simply be reused.

One or more instances of CAD model 112 are used by simulator 104 to prepare images of the instances of CAD model 112 in random poses. Simulator 104 may be used so that the actual pose of each instance of CAD model 112, sometimes referred to as the “ground truth”, can be easily output from the simulator. In this manner, manual derivation of actual poses, which can be very tedious and time consuming, is not necessary. A random pose of each instance of CAD model 112 may be achieved by letting the objects fall, collide, shake, stir, etc. within the simulation. Simulator 104 uses a physics engine to simplify these manipulations. Once each instance of CAD model 112 has settled into a resting position, an image is captured. Features that do not correlate with pose can be randomized. Therefore, lighting effects can be altered, and surface color, texture, and shininess can be all be randomized. Doing so may effectively cause the learning process to focus on features that do correlate with pose, such as shape data, edges, etc. to determine the pose. Noise can be added to the pictures, so that the learning process may become accustomed to the imperfections of real images of physical objects. Lighting effects also play a role in this, because real images may not always be taken under ideal lighting conditions, which may leave some pertinent aspects difficult to detect.

Each color image captured from simulator 104 is paired with the corresponding actual pose output from simulator 104, which is used as the label. In this embodiment, the learning process is an untrained convolutional neural network 117U, which is applied to each color image and label pair. The pairs of color images and labels make up the training data. The training data can be generated before or during the training process. In embodiments where the training data is generated using computational resources that are separate from those of the training process, it may be more temporally efficient to apply each pair as it is generated. During the training process, output from untrained convolutional neural network 117U is compared with the corresponding label, and weights are adjusted accordingly. The training process will continue until a condition indicating that training is complete is met. This condition may be application of a certain amount of training data, a settling of the weights of untrained convolutional neural network 117U, the output reaching a threshold accuracy, etc.

Once the training is complete, a resulting trained convolutional neural network 117T is ready to be used in a physical environment. In this embodiment, the physical environment includes physical objects that are identical to CAD model 112. These physical objects are photographed by a camera 125, resulting in a color image of one or more of the physical objects. Trained convolutional neural network 117T is applied to the color image to output a 6D pose of each physical object in the color image. Although camera 125 may be a more basic, less sophisticated camera, and lighting conditions may not be ideal, trained convolutional neural network 117T should be able to properly process this color image in the same manner as with the simulated images during training.

Once the 6D pose of each physical object in the color image is output, one final operation of refinement 109 is performed. Refinement operation 109 utilizes CAD model 112 once again to make fine adjustments to each detected 6D pose. In this embodiment, CAD model 112 is used to recreate the image according to each output 6D pose, then make adjustments to the 6D pose of any object that appears offset between the images. As the 6D poses are adjusted, the recreated image is manipulated accordingly, and the comparison continues until the images match. In this embodiment, refinement operation 109 is a classical handwritten algorithm rather than another learning process.

Once refinement 109 is complete, final pose 119 is output. Final pose 119 can be utilized in a variety of ways depending on the situation of the embodiment. For example, in an assembly line, a robot arm can utilize final pose 119 to strategically grab each physical object in a manner allowing the robot arm to perform a step of assembly. There are plenty of applications outside of robot arms, and even assembly lines. The number of applications in need of proper pose detection is increasing.

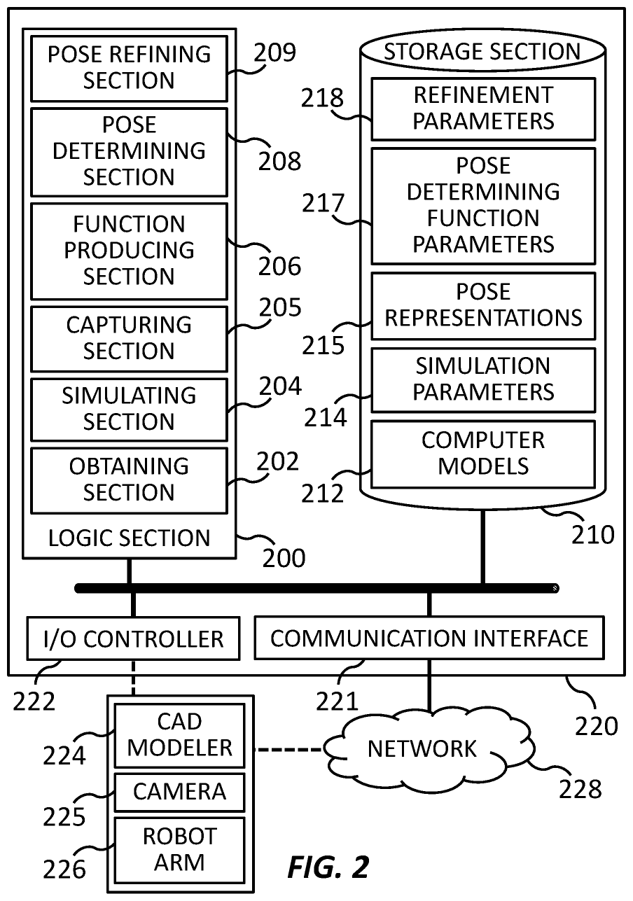

FIG. 2 shows an exemplary hardware configuration for pose detection, according to an embodiment of the present invention. The exemplary hardware configuration includes pose detection device 220, which communicates with network 228, and may interact with CAD modeler 224, camera 225, and robot arm 226. Pose detection device 220 may be a host computer such as a server computer or a mainframe computer that executes an on-premise application and hosts client computers that use it, in which case pose detection device 220 may not be directly connected to CAD modeler 224, camera 225, and robot arm 226, but is connected through network 228. Pose detection device 220 may be a computer system that includes two or more computers. Pose detection device 220 may be a personal computer that executes an application for a user of pose detection device 220.

Pose detection device 220 includes a logic section 200, a storage section 210, a communication interface 221, and an input/output controller 222. Logic section 200 may be a computer program product including one or more computer readable storage mediums collectively storing program instructions that are executable by a processor or programmable circuitry to cause the processor or programmable circuitry to perform the operations of the various sections. Logic section 200 may alternatively be analog or digital programmable circuitry, or any combination thereof. Logic section 200 may be composed of physically separated storage or circuitry that interacts through communication. Storage section 210 may be a non-volatile computer-readable medium capable of storing non-executable data for access by logic section 200 during performance of the processes herein. Communication interface 221 reads transmission data, which may be stored on a transmission buffering region provided in a recording medium, such as storage section 210, and transmits the read transmission data to network 228 or writes reception data received from network 228 to a reception buffering region provided on the recording medium. Input/output controller 222 connects to various input and output units, such as CAD modeler 224, camera 225, and robot arm 226, via a parallel port, a serial port, a keyboard port, a mouse port, a monitor port, and the like to accept commands and present information.

Obtaining section 202 is the portion of logic section 200 that performs obtaining data from CAD modeler 224, camera 225, robot arm 226, and network 228, in the course of pose detection. Obtaining section may obtain a computer model 212 of a physical object. Obtaining section 202 may store computer models 212 in storage section 210. Obtaining section 202 may include sub-sections for performing additional functions, as described in the flow charts below. Such sub-sections may be referred to by a name associated with their function.

Simulating section 204 is the portion of logic section 200 that simulates the computer model in a realistic environment. Simulating section 204 may simulate a computer model of a physical object in a random pose. In doing so, simulating section 204 may include a physics engine such as to induce motion of the computer model. Simulating section 204 may store simulation parameters 214, such as the physics engine, in storage section 210. Simulating section 204 may include sub-sections for performing additional functions, as described in the flow charts below. Such sub-sections may be referred to by a name associated with their function.

Capturing section 205 is the portion of logic section 200 that captures training data. Training data may include a plurality of pose representations 215, each pose representation 215 including an image of the computer model in one of a plurality of poses paired with a label including a pose specification of the computer model as shown in the image. The images and corresponding pose specifications are defined by simulating section 204. Capturing section 205 may store pose representations 215 in storage section 210. Capturing section 205 may include sub-sections for performing additional functions, as described in the flow charts below. Such sub-sections may be referred to by a name associated with their function.

Function producing section 206 is the portion of logic section 200 that applies a learning process to the pose representations to produce a pose determining function in the course of pose detection. For example, the pose determining function may relate an image of the object to a pose specification. Function producing section 206 may store parameters of the trained learning process in storage 210, such as pose determining function parameters 217. Function producing section 206 may include sub-sections for performing additional functions, as described in the flow charts below. Such sub-sections may be referred to by a name associated with their function.

Pose determining section 208 is the portion of logic section 200 that determines a pose specification of the physical object by applying the pose determining function to the image of the physical object in the course of pose detection. For example, the pose specification is a 6D specification of the position and orientation. In doing so, pose determining section 208 may utilize pose determining function parameters 217 stored in storage 210, and an image of a physical object identical to computer model 212 in a physical environment captured by camera 224, resulting in an output of a 6D pose specification. Pose determining section 208 may include sub-sections for performing additional functions, as described in the flow charts below. Such sub-sections may be referred to by a name associated with their function.

Pose refining section 209 is the portion of logic section 200 that refines the pose specification of the physical object in the course of pose detection. In doing so, pose refining section 209 may utilize refinement parameters 218 and computer model 212 stored in storage 210, resulting in an output of a refined 6D pose specification. Pose refining section 209 may include sub-sections for performing additional functions, as described in the flow charts below. Such sub-sections may be referred to by a name associated with their function.

In this embodiment, pose detection device 220 may make it possible to generate training data, train the learning process to produce the pose determining function, and then put the trained pose determining function to use, automatically, by simply inputting a computer model.

In other embodiments, the pose detection device may be any other device capable of processing logical functions in order to perform the processes herein. The pose detection device may not need to be connected to a network in environments where the input, output, and all information is directly connected. The logic section and the storage section need not be entirely separate devices, but may share one or more computer-readable mediums. For example, the storage section may be a hard drive storing both the computer-executable instructions and the data accessed by the logic section, and the logic section may be a combination of a central processing unit (CPU) and random access memory (RAM), in which the computer-executable instructions may be copied in whole or in part for execution by the CPU during performance of the processes herein. In embodiments that utilize neural networks especially, one or more graphics processing units (GPU) may be included in the logic section.

In embodiments where the pose detection device is a computer, a program that is installed in the computer can cause the computer to function as or perform operations associated with apparatuses of the embodiments of the present invention or one or more sections (including modules, components, elements, etc.) thereof, and/or cause the computer to perform processes of the embodiments of the present invention or steps thereof. Such a program may be executed by a processor to cause the computer to perform certain operations associated with some or all of the blocks of flowcharts and block diagrams described herein.

In other embodiments, the camera may be a depth camera, capable of capturing depth information of each pixel in addition to color information. In such embodiments, the capturing section would also capture depth information defined by the simulating section, and the learning function would be trained accordingly. In other words, the image of the computer model may include depth information, and therefore the capturing the image of the physical object includes capturing depth information as well. However, many depth cameras may not have good accuracy at small distances. Therefore, depth cameras may be more suitable for larger scale applications.

In some embodiments, multiple computer models can be used for a single application. Multiple computer models can be simulated in the simulating section with ease, but more training may be required to produce a reliable pose determining function. For example, if a single object include two connected yet relatively movable components, such components may be treated as individual objects, and the learning function would be trained accordingly. In further embodiments, the label may include a parameter defining the relationship between the components. Objects that change shape in more complex ways, such as objects that flow, deform, or that have many moving parts, may not be able to produce a reliable pose determining function at all.

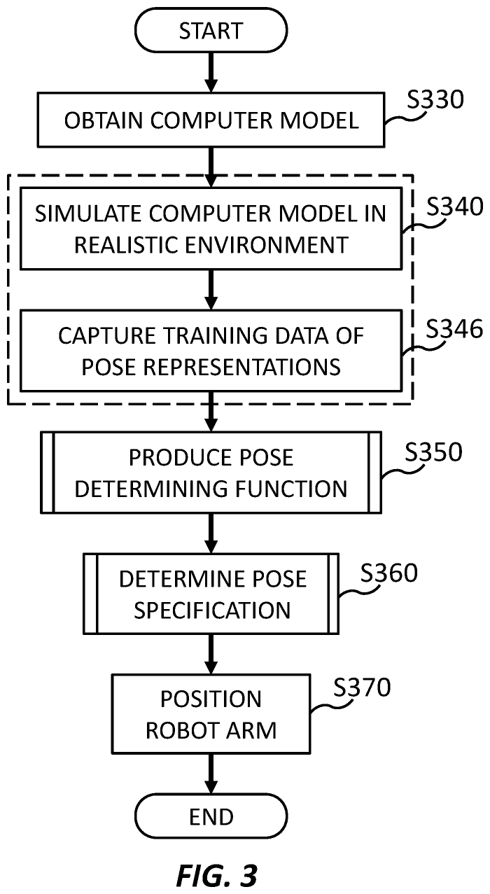

FIG. 3 shows an operational flow for pose detection, according to an embodiment of the present invention. The operational flow may provide a method of pose detection that may be performed by a pose detection device, such as pose detection device 220, or any other device capable of performing the following operations.

At S330, an obtaining section, such as obtaining section 202, obtains a computer model. For example, the obtaining section may obtain a computer model of a physical object from direct user input, such as from a CAD modeler, such as CAD modeler 224, or from another source through a network, such as network 228. In some embodiments, the obtaining section may generate the computer model by 3D scanning the physical object.

At S340, a simulating section, such as simulating section 204, simulates the computer model in a realistic environment. For example, the simulating section may simulate the computer model in a realistic environment. In some embodiments, the simulating section may simulate more than one instance of the computer model at the same time.

At S346, a capturing section, such as capturing section 205, captures training data of pose representations. For example, the capturing section may capture a plurality of pose representations, each pose representation including an image of the computer model in one of a plurality of poses paired with a label including a pose specification of the computer model as shown in the image. The images and corresponding pose specifications are defined by the simulating section. In embodiments where the simulating section simulates more than one instance of the computer model, each image may also include more than one instance of the computer model, each instance of the computer model being in a unique pose.

At S350, a function producing section, such as function producing section 206, produces a pose determining function. For example, the function producing section may apply a learning process to the pose representations to produce a pose determining function that relates an image of the object to a pose specification.

At S360, a pose determining section, such as pose determining section 208, determines a pose specification. For example, the pose determining section may determine a pose specification of the physical object by applying the pose determining function to the image of the physical object in the course of pose detection. In some embodiments, a pose refining section, such as pose refining section 209, may refine the pose specification of the physical object. In some embodiments, the pose refining section may apply Direct Image Alignment (DIA) to reduce a difference between the image of the computer model according to the pose specification of the physical object and the image of the physical object in the physical environment. In some embodiments, such as those where depth information is available, the pose refining section may apply Coherent Point Drift (CPD) to reduce a difference between the image of the computer model according to the pose specification of the physical object and the image of the physical object in the physical environment.

At S370, a robot arm, such as robot arm 226, may be positioned. For example, the pose detection device may position a robot arm in accordance with the pose specification. In some embodiments, positioning the robot arm may include determining the location of the physical object relative to the robot arm based on the location of a camera that captured the image of the physical object, such as camera 225.

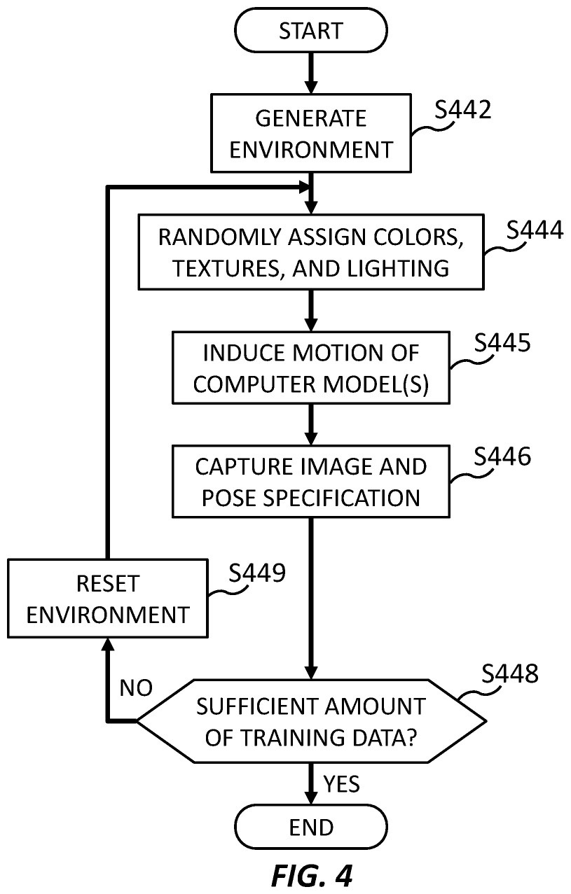

FIG. 4 shows an operational flow for simulation of a computer model to capture training data, such as S340 and S346 in FIG. 3, according to an embodiment of the present invention. The operations within this operational flow may be performed by a simulating section, such as simulating section 204, or a correspondingly named sub-section thereof, and a capturing section, such as capturing section 205, or a correspondingly named sub-section thereof.

At S442, an environment generating section, such as simulating section 204 or a subsection thereof, generates a simulated environment. For example, the environment generating section may create a 3D space within which to render the computer model and some form a platform. The remaining details of the environment, such as background color and objects, if any, are largely inconsequential to the goals of the simulation, and furthermore are randomized to prevent the learning process from assigning value to them.

At S444, a random assignment section, such as simulating section 204 or a subsection thereof, randomly assigns colors, textures, and lighting. For example, the random assignment section may randomly assign, within the realistic environment simulator, one or more surface colors to the computer model and the platform for each pose. As another example, the random assignment section may randomly assign, within the realistic environment simulator, one or more surface textures to the computer model and the platform for each pose. As yet another example, the random assignment section may randomly assign, within the realistic environment simulator, a lighting effect in the environment for each pose. Such a lighting effect may include at least one of brightness, contrast, color temperature, and direction.

At S445, a motion inducement section, such as simulating section 204 or a subsection thereof, induces motion of the computer model. For example, the motion inducement section may induce motion, within the realistic environment simulator, of the computer model with respect to a platform so that the computer model assumes a random pose. Examples of the induced motion include dropping, spinning, and colliding the computer model with respect to the platform or other instances of the computer model.

At S446, a capturing section, such as capturing section 205, may capture an image and a pose specification. For example, the capturing section may capture an image of the computer model within the simulation, such as by defining a soft camera within the simulation, and using the soft camera to capture an image of the computer model. The capturing section may also capture the pose specification of the computer model. The pose specification may be from the point of view of the soft camera. Alternatively, the pose specification may be from some other point of view, such as by converting the pose specification. In embodiments where the simulating section simulates more than one instance of the computer model, each image may also include more than one instance of the computer model, each instance of the computer model being in a unique pose and thus being associated with a unique pose specification.

At S448, the simulating section determines whether a sufficient amount of training data has been captured by the capturing section. If there is an insufficient amount of training data, then the operational flow proceeds to S449, where the environment is reset to prepare for another training data capture. If there is a sufficient amount of training data, then the operational flow ends.

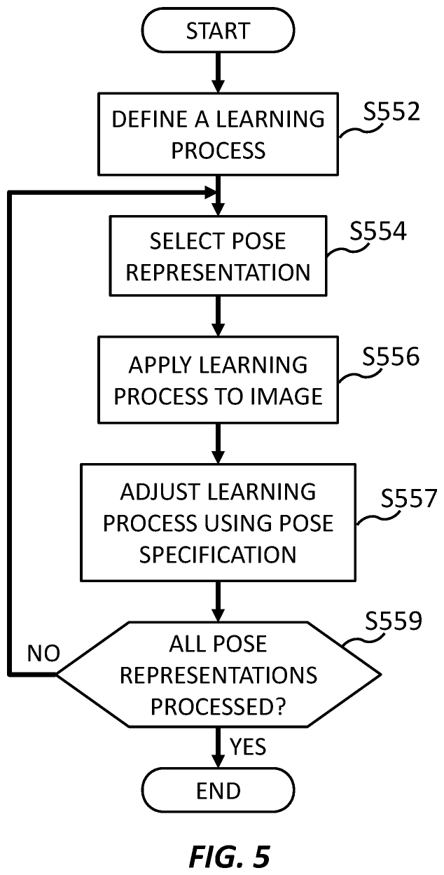

FIG. 5 shows an operational flow for producing a pose determining function, such as S350 in FIG. 3, according to an embodiment of the present invention. The operations within this operational flow may be performed by a function producing section, such as function producing section 206, or a correspondingly named sub-section thereof.

At S552, a learning process defining section, such as function producing section or a subsection thereof, defines a learning process. Defining a learning process may include defining a type of neural network, dimensions of the neural network, number of layers, etc. In some embodiments, the learning process defining section defines the learning process as a convolutional neural network.

At S554, a pose representation selecting section, such as function producing section or a subsection thereof, selects a pose representation among the pose representations. As iterations of the operational flow for producing a pose determining function proceed, only previously unselected pose representations may be selected at S554, to ensure that each pose representation is processed. In embodiments in which pose representations are processed as soon as they are captured, pose representation selection may not be necessary.

At S556, a learning process applying section, such as function producing section or a subsection thereof, applies the learning process to an image. Applying the learning process to the pose representation may include using the image as input into the learning process so that the learning process generates an output. In embodiments where the learning process includes a neural network, and the pose representation is a simulated image, the learning process may output a 6D pose specification.

At S557, a learning process adjusting section, such as function producing section or a subsection thereof, adjusts the learning process using the label, the pose specification defined by the simulating section, as a target. As iterations of the operational flow for producing a pose determining function proceed, the learning process adjusting section adjusts the parameters of the learning process, such as pose determining function parameters 217, to train the learning process to become a pose determining function. In embodiments where the learning process includes a neural network, and the pose representation is a simulated image, the learning process adjusting section may adjust the weights of the neural network, and the learning process may be trained to output a 6D pose specification for each instance of the computer model within the image. For example, after the image is input into the neural network, the error between the actual output of the neural network and the corresponding pose specification is computed. Once the error is computed, this error is then backpropagated, i.e.—the error is represented as a derivative with respect to each weight of the network. Once the derivative is obtained, the weights of the neural network are updated according to a function of this derivative.

At S559, the function producing section determines whether all of the pose representations have been processed by the function producing section. If any pose representations remain unprocessed, then the operational flow returns to S554, where another pose representation is selected for processing. If no pose representations remain unprocessed, then the operational flow ends. As the operational flow of FIG. 5 is iteratively performed, the iterations of operations S554, S556, and S557 collectively amount to an operation of producing a pose determining function. At the end of the operational flow of FIG. 5, the learning process has received sufficient training to become a pose determining function.

Although in this embodiment the training ends when all of the pose representations have been processed, other embodiments may include different criteria for determining when training ends, such as by a number of epochs, or in response to amount of error, etc. Also, although in this embodiment, the parameters of the learning process are adjusted after application of each pose representation, other embodiments may adjust the parameters at different intervals, such as once for each epoch, or in response to amount of error, etc. Finally, although in this embodiment, the output of the learning process becomes the pose determining function, meaning that the output of the learning function is the pose specification, in other embodiments the learning process may not output the pose specification itself, but some output that is combined with parameters of the camera to result in the pose specification. In these embodiments, the training data may be produced by removing such parameters of the camera from the pose specification, to properly define the target learning process output. In these embodiments, the pose determining function includes both the trained learning process and the function for combining output with camera parameters.

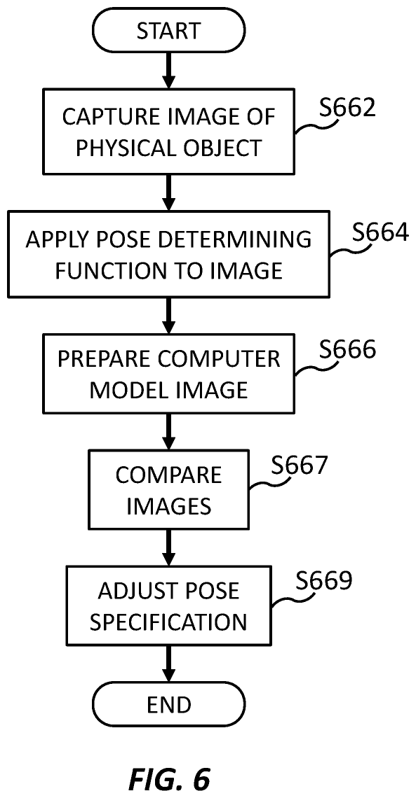

FIG. 6 shows an operational flow for determining a pose specification, such as S360 in FIG. 3, according to an embodiment of the present invention. The operations within this operational flow may be performed by a pose determining section, such as pose determining section 208, or a correspondingly named sub-section thereof, and pose refining section, such as pose refining section 209, or a correspondingly named sub-section thereof.

At S662, an image capturing section, such as pose determining section 208 or a subsection thereof, captures an image of a physical object. For example, the image capturing section may capture an image of the physical object in a physical environment. The image capturing section may communicate with a camera, such as camera 225, or other photo sensor to capture the image. Although the pose determining function may be effectively trained not to allow color information to influence the output pose specification, images captured in color can provide more information such that edges have larger deviations in information representing them than images captured in, for example, grayscale, that could allow the pose determining function to more easily detect the edges that define the physical object in the image.

At S664, a pose determining function applying section, such as pose determining section 208, or a correspondingly named sub-section thereof, applies the pose determining function to the image. Applying the pose determining function to the image may include using the image as input into the pose determining function so that the pose determining function generates an output. In embodiments where the pose determining function includes a neural network, the neural network may output a 6D pose specification for each instance of the computer model in the image.

At S666, an image preparing section, such as pose refining section 209, or a correspondingly named sub-section thereof, prepares an image of the computer model. For example, the image preparing section may prepare an image of the computer model according to the pose specification of the physical object. In some embodiments, the image consists exclusively of the computer model according to the pose specification, with a plain background.

At S667, an image comparing section, such as pose refining section 209, or a correspondingly named sub-section thereof, compares the prepared image with the captured image. For example, the image comparing section may compare the image of the computer model according to the pose specification of the physical object to the image of the physical object in the physical environment. In some embodiments, a silhouette, which may be produced by segmenting the prepared image, is compared with a silhouette of the prepared image computed directly from the simulation to facilitate the comparison. This comparison may be performed iteratively until an error is sufficiently minimized.

At S669, a pose adjusting section, such as pose refining section 209, or a correspondingly named sub-section thereof, adjusts the pose specification output from the pose determining function. For example, the pose adjusting section may adjust the pose specification to reduce a difference between the captured image and the prepared image.

In many of the embodiments herein, a pose detection device may make it possible to generate training data, train the learning process to produce the pose determining function, and then put the trained pose determining function to use, automatically, by simply inputting a computer model. By utilizing a simulator to generate training data, the embodiments described herein may be capable of rapid image capturing that includes capturing of the pose specification defined by the simulator as the label. Using the pose specification defined by the simulator allows the label to be very accurate as well. Existing simulators known for their realistic accuracy, such as the UNREAL® engine, may not only increase the accuracy confidence, but also have built-in capabilities for image processing and environmental aspect randomization.

Various embodiments of the present invention may be described with reference to flowcharts and block diagrams whose blocks may represent (1) steps of processes in which operations are performed or (2) sections of apparatuses responsible for performing operations. Certain steps and sections may be implemented by dedicated circuitry, programmable circuitry supplied with computer-readable instructions stored on computer-readable media, and/or processors supplied with computer-readable instructions stored on computer-readable media. Dedicated circuitry may include digital and/or analog hardware circuits and may include integrated circuits (IC) and/or discrete circuits. Programmable circuitry may include reconfigurable hardware circuits comprising logical AND, OR, XOR, NAND, NOR, and other logical operations, flip-flops, registers, memory elements, etc., such as field-programmable gate arrays (FPGA), programmable logic arrays (PLA), etc. Processors may include central processing units (CPU), graphics processing units (GPU), mobile processing units (MPU), etc.

Computer-readable media may include any tangible device that can store instructions for execution by a suitable device, such that the computer-readable medium having instructions stored therein comprises an article of manufacture including instructions which can be executed to create means for performing operations specified in the flowcharts or block diagrams. Examples of computer-readable media may include an electronic storage medium, a magnetic storage medium, an optical storage medium, an electromagnetic storage medium, a semiconductor storage medium, etc. More specific examples of computer-readable media may include a floppy disk, a diskette, a hard disk, a random access memory (RAM), a read-only memory (ROM), an erasable programmable read-only memory (EPROM or Flash memory), an electrically erasable programmable read-only memory (EEPROM), a static random access memory (SRAM), a compact disc read-only memory (CD-ROM), a digital versatile disk (DVD), a BLU-RAY® disc, a memory stick, an integrated circuit card, etc.

Computer-readable instructions may include assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, JAVA, C++, etc., and conventional procedural programming languages, such as the “C” programming language or similar programming languages.

Computer-readable instructions may be provided to a processor of a general purpose computer, special purpose computer, or other programmable data processing apparatus, or to programmable circuitry, locally or via a local area network (LAN), wide area network (WAN) such as the Internet, etc., to execute the computer-readable instructions to create means for performing operations specified in the flowcharts or block diagrams. Examples of processors include computer processors, processing units, microprocessors, digital signal processors, controllers, microcontrollers, etc.

Many of the embodiments of the present invention include artificial intelligence, learning processes, and neural networks in particular. Some of the foregoing embodiments describe specific types of neural networks. However, a learning process usually starts as a configuration of random values. Such untrained learning processes must be trained before they can be reasonably expected to perform a function with success. Many of the processes described herein are for the purpose of training a learning process for pose detection. Once trained, a learning process can be used for pose detection, and may not require further training. In this way, a trained pose determining function is a product of the process of training an untrained learning process.

While the embodiments of the present invention have been described, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

What is claimed is:

1. A computer readable medium storing instructions that, when executed by a computer, cause the computer to perform operations comprising:
obtaining a computer model of a physical object;
simulating the computer model in a realistic environment simulator;
capturing training data including a plurality of pose representations, each pose representation including an image of the computer model in one of a plurality of poses paired with a label including a pose specification of the computer model as shown in the image, the image of the computer model and the pose specification defined by the simulator;
applying a learning process to the pose representations to produce a pose determining function for relating an image of the object to a pose specification.

2. The computer readable medium according to claim 1, wherein the operations further comprise:
capturing an image of the physical object in a physical environment;
determining a pose specification of the physical object by applying the pose determining function to the image of the physical object.

3. The computer program according to claim 2, wherein the operations further comprise positioning a robot arm in accordance with the pose specification.

4. The computer readable medium according to claim 2, wherein the positioning the robot arm includes determining the location of the physical object relative to the robot arm based on the location of a camera that captured the image of the physical object.

5. The computer readable medium according to claim 2, wherein the operations further comprise refining the pose specification of the physical object.

6. The computer readable medium according to claim 5, wherein the refining includes preparing an image of the computer model according to the pose specification of the physical object.

7. The computer readable medium according to claim 6, wherein the refining further includes
comparing the image of the computer model according to the pose specification of the physical object to the image of the physical object in the physical environment, and
adjusting the pose specification to reduce a difference between the captured image and the prepared image.

8. The computer readable medium according to claim 5, wherein the refining further includes applying one of Direct Image Alignment (DIA) and Coherent Point Drift (CPD) to reduce a difference between the image of the computer model according to the pose specification of the physical object and the image of the physical object in the physical environment.

9. The computer readable medium according to claim 1, wherein the pose specification is a 6D specification of the position and orientation.

10. The computer readable medium according to claim 1, wherein
the simulating includes simulating more than one instance of the computer model, and
each image includes the more than one instance of the computer model, each instance of the computer model being in a unique pose.

11. The computer readable medium according to claim 1, wherein
the simulator includes a physics engine, and
the simulating includes inducing motion, within the realistic environment simulator, of the computer model with respect to a platform so that the computer model assumes a random pose.

12. The computer readable medium according to claim 11, wherein the inducing motion includes at least one of dropping, spinning, and colliding.

13. The computer readable medium according to claim 11, wherein the simulating includes randomly assigning, within the realistic environment simulator, one or more surface colors to the computer model and the platform for each pose.

14. The computer readable medium according to claim 11, wherein the simulating includes randomly assigning, within the realistic environment simulator, one or more surface textures to the computer model and the platform for each pose.

15. The computer readable medium according to claim 1, wherein the simulating includes randomly assigning, within the realistic environment simulator, a lighting effect in the environment for each pose.

16. The computer readable medium according to claim 15, wherein the lighting effect includes at least one of brightness, contrast, color temperature, and direction.

17. The computer readable medium according to claim 1, wherein
the image of the computer model includes depth information, and
the capturing the image of the physical object includes capturing depth information.

18. The computer readable medium according to claim 1, wherein the learning process is a convolutional neural network.

19. A computer-implemented method comprising:
obtaining a computer model of a physical object;
simulating the computer model in a realistic environment simulator;
capturing training data including a plurality of pose representations, each pose representation including an image of the computer model in one of a plurality of poses paired with a label including a pose specification of the computer model as shown in the image, the image of the computer model and the pose specification defined by the simulator;
applying a learning process to the pose representations to produce a pose determining function for relating an image of the object to a pose specification.

20. An apparatus comprising:
an obtaining section configured to obtain a computer model of a physical object;
a simulating section configured to simulate the computer model in a realistic environment simulator;
a capturing section configured to capture training data including a plurality of pose representations, each pose representation including an image of the computer model in one of a plurality of poses paired with a label including a pose specification of the computer model as shown in the image, the image of the computer model and the pose specification defined by the simulator;
a learning process applying section configured to apply a learning process to the pose representations to produce a pose determining function for relating an image of the object to a pose specification.
